(19) United States
(12) Patent Application Publication
(10) Pub. No.: US 2026/0164750 A1
(43) Pub. Date: Jun. 11, 2026

(54) BACKSIDE CONTACT FORMATION FOR TOP FET IN A MONOLITHIC STACKED FET

(71) Applicant: International Business Machines Corporation, Armonk, NY (US)

(72) Inventors: Sarah Nahar Chowdhury, Guilderland, NY (US); Ruilong Xie, Niskayuna, NY (US); HUIMEI ZHOU, Albany, NY (US); Nicolas Jean Loubet, GUILDERLAND, NY (US); Shahrukh Khan, Sandy Hook, CT (US); Chen Zhang, Santa Clara, CA (US)

(21) Appl. No.: 18/976,207

(22) Filed: Dec. 10, 2024

(51) Int. Cl. H10D 64/23; H10D 30/00; H10D 62/10; H10D 84/01; H10D 84/83

(52) U.S. Cl. CPC H10D 64/254; H10D 84/0149; H10D 84/8312; H10D 84/832; H10D 30/501; H10D 62/121

(57) ABSTRACT

Embodiments of the invention disclose structures and methods for making the structures. According to an embodiment, the structure may include a top transistor stacked on a bottom transistor, wherein top nanosheet stacks of the top transistor are vertically aligned to bottom nanosheet stacks of the bottom transistor, and wherein a top source/drain region of the top transistor is connected to backside interconnects by an extension region, a backside contact, and a backside via.

### BACKGROUND

The present invention generally relates to semiconductor structures, and more particularly related to backside contact formation for top FET in a monolithic stacked FET.

For an I-shaped stacked FET, forming backside contacts for the top source/drain regions is very challenging. Currently, the front-up approach is to use CA-RV connection to wire the top source/drain region to the backside where the top and bottom FET are stacked. This leads to middle-of-line (MOL) congestion and a tight contact area tip-to-tip (T2T) space. Moreover, this causes high resistance and possibility of shorting, degrading the device performance.

### SUMMARY

According to an embodiment of the present invention, a structure is provided. The structure may include a top transistor stacked on a bottom transistor, wherein top nanosheet stacks of the top transistor are vertically aligned to bottom nanosheet stacks of the bottom transistor, and wherein a top source/drain region of the top transistor is connected to backside interconnects by an extension region, a backside contact, and a backside via.

According to another embodiment of the present invention, a structure is provided. The structure may include a top transistor stacked on a bottom transistor, wherein a top source/drain region of the top transistor is connected to backside interconnects by an extension region and backside contact.

According to yet another embodiment of the present invention, a method is provided. The method includes forming a bottom layer device source/drain region with spacer confinement and forming a top layer device source/drain region without spacer confinement. The method further includes forming a backside contact trench for the top layer device source/drain region through a sidewall surface of the top layer device source/drain region and forming a backside contact placeholder for the top layer device source/drain region. In addition, the method includes forming a trench epi to connect the top layer device source/drain region to the backside contact placeholder and flipping a wafer on which the top layer device and the bottom layer device are formed. Lastly, the method includes removing the backside contact placeholder and forming a backside contact.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a top view of a generic structure shown to provide spatial context to the different cross-sectional views and structural orientations of the semiconductor structures shown in the subsequent figures;

FIG. 2 and FIG. 3 are cross-sectional views of a semiconductor structure 100, according to an embodiment of the invention;

FIG. 4 and FIG. 5 are cross-sectional views of the semiconductor structure 100, according to an embodiment of the invention;

FIG. 6 and FIG. 7 are cross-sectional views of the semiconductor structure 100, according to an embodiment of the invention;

FIG. 8 and FIG. 9 are cross-sectional views of the semiconductor structure 100, according to an embodiment of the invention;

FIG. 10 and FIG. 11 are cross-sectional views of the semiconductor structure 100, according to an embodiment of the invention;

FIG. 12 and FIG. 13 are cross-sectional views of the semiconductor structure 100, according to an embodiment of the invention;

FIG. 14 and FIG. 15 are cross-sectional views of the semiconductor structure 100, according to an embodiment of the invention;

FIG. 16 and FIG. 17 are cross-sectional views of the semiconductor structure 100, according to an embodiment of the invention;

FIG. 18 and FIG. 19 are cross-sectional views of the semiconductor structure 100, according to an embodiment of the invention;

FIG. 20 and FIG. 21 are cross-sectional views of the semiconductor structure 100, according to an embodiment of the invention;

FIG. 22 and FIG. 23 are cross-sectional views of the semiconductor structure 100, according to an embodiment of the invention;

FIG. 24 and FIG. 25 are cross-sectional views of the semiconductor structure 100, according to an embodiment of the invention;

FIG. 26 and FIG. 27 are cross-sectional views of the semiconductor structure 100, according to an embodiment of the invention;

FIG. 28 and FIG. 29 are cross-sectional views of the semiconductor structure 100, according to an embodiment of the invention; and

FIG. 30 and FIG. 31 are cross-sectional views of the semiconductor structure 100, according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, regions or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sublithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10°deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention generally relates to semiconductor structures, and more particularly related to backside contact formation for top FET in a monolithic stacked FET.

A current trend in semiconductor device technology is shrinking device size to increase overall circuit density. This trend results in innovations like a stacked FET where multiple transistors are stacked on top of each other. However, as noted above, forming backside contacts for the top source/drain regions on stacked FET is very challenging, particularly for an I-shaped stacked FET. Currently, the front-up approach is to use CA-RV connection to wire the top source/drain region to the backside where the top and bottom FET are stacked. This approach, however, leaves only a narrow space for connecting the top S/D region to the backside contact with a long I-shaped contact. This front-up approach hence results in narrow top device tip-to tip contact space and requires additional innovation in the device architecture. Further, this leads to middle-of-line (MOL) congestion, which may cause high resistance and possibility of shorting, thereby degrading the overall device performance.

The claimed invention is intended to address the shortcomings in the state of the art detailed above. In particular, the claimed invention moves the RV from a congested MOL area between the upper source/drain regions to a side of the upper source drain regions. The RV is then connected to an extension region that connects to the backside contact and backside interconnect. This results in an improved (e.g., increased) T2T spacing between contacts within the MOL.

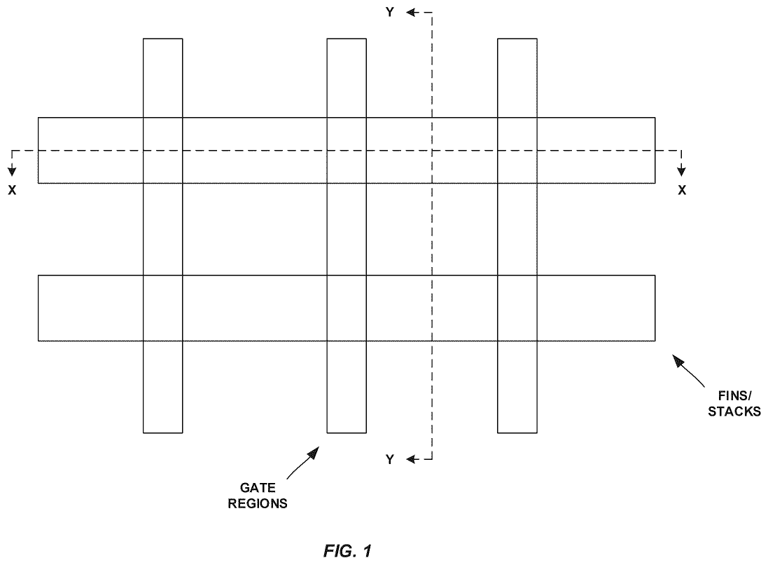

Referring now to FIG. 1, a top view of a generic structure is shown to provide spatial context to the different cross-sectional views and structural orientations of the semiconductor structures shown in the figures and described below.

The generic structure illustrated in FIG. 1 shows multiple fins/stacks and multiple gate regions situated perpendicular to one another. FIG. 1-31 represent cross section views oriented as indicated in FIG. 1.

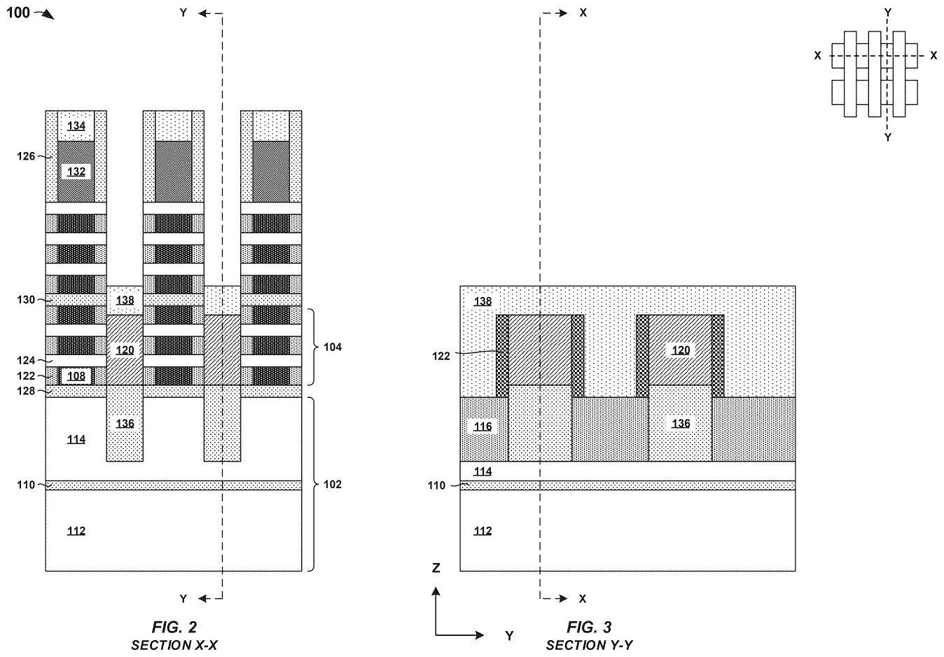

Referring now to FIG. 2 and FIG. 3, a structure 100 is shown during an intermediate step of a method of fabricating a semiconductor structure, according to an embodiment of the invention. FIG. 2 depicts a cross-sectional view of the structure 100 shown in FIG. 3 taken along line XX and FIG. 3 depicts a cross-sectional view of the structure 100 shown in FIG. 2 taken along line YY.

The structure 100 includes a substrate 102 and arrays of nanosheet stacks 104.

The substrate 102 may be a layered semiconductor such as a silicon-on-insulator (SOI) or SiGe-on-insulator. As illustrated, the substrate 102 includes a base substrate 112, an etch stop layer 110, and a top semiconductor layer 114.

In the present embodiment, the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon.

The etch stop layer 110 separates the base substrate 112 from the top semiconductor layer 114. The etch stop layer 110 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

As illustrated, the arrays of nanosheet stacks 104 include a plurality of silicon channels 124 and one or more sacrificial gates 108. The silicon channels 124 are surrounded on four sides (top, bottom, into page (not shown by cross-section), out of page (not shown by cross-section)) by a single sacrificial gate of the one or more sacrificial gates 108. In an embodiment, the sacrificial gates 108 may be SiGe. As illustrated, the structure 100 may include multiple arrays of nanosheet stacks that are stacked on top of another, in this case forming two stacked transistors. In this embodiment, it is noted that the arrays of nanosheet stacks are vertically aligned. As used herein, the array of nanosheet stacks 104 on the bottom of the stack may be referred to as a “bottom transistor” or “bottom nanosheet stacks” while the array of nanosheet stacks on top of the stack may be referred to as a “top transistor” or “top nanosheet stacks.” Similarly, components of the top transistor may be prefaced as “top” components while components of the bottom transistor may be prefaced as “bottom” components. For example, a source/drain region of the top transistor may be referred to as a top source/drain region, and so forth. The arrays of nanosheet stacks 104 are formed on the substrate 102 in accordance with known techniques.

For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The structure 100 further includes shallow trench isolation (STI) regions 116, placeholders 136, and source/drain regions 120.

As illustrated, the STI regions 116 extends partially into the top semiconductor layer 114. The STI regions 116 may each include an isolation fill. For example, the isolation fill is silicon oxide (SiOx) or silicon nitride (SiN).

The placeholders 136 are formed by filling self-aligned openings in the top semiconductor layer 114 between adjacent nanosheet stacks 104 with a sacrificial material according to known techniques. In an embodiment, the sacrificial material is silicon germanium or amorphous silicon epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the silicon channels 124.

The source/drain regions 120 are formed on top of the placeholders 136 and generally arranged between adjacent nanosheet stacks 104 according to known techniques. Specifically, the source/drain regions 120 are disposed between adjacent nanosheet stacks 104 in direct contact with exposed ends of the silicon channels 124. The source/drain regions 120 may be epitaxially grown from the exposed ends of the silicon channels 124 according to known techniques.

The structure 100 further includes inner spacers 122, gate spacers 126, a bottom dielectric isolation (BDI) 128, a middle dielectric isolation (MDI) 130, and an interlayer dielectric (ILD) 138.

The inner spacers 122 are disposed between alternate silicon channels 124 and laterally separate the sacrificial gates 108 and other subsequently formed structures from the source/drain regions 120, as illustrated. The inner spacers 122 provide necessary electrical insulation between the sacrificial gates 108/subsequently formed structures and the source/drain regions 120.

The gate spacers 126 are added to define a length of the silicon channels 124 and the source/drain regions 120. The gate spacers 126 are critical for electrically insulating the sacrificial gates 108 and other subsequently formed structures from other subsequently formed structures, for example, upper source/drain regions (not shown) and source/drain contacts (not shown).

As illustrated, the BDI 128 separates the substrate 102 from the array of nanosheet stacks 104. The BDI 128 may be conformally formed on the top semiconductor layer 114 such that it surrounds a top of the placeholders 136. The inner spacers 122 may be deposited conformally on top of the BDI 128.

As illustrated, the MDI 130 may be formed conformally on top of the inner spacers 122 such that they surround the sacrificial gates 108 as well as separate stacks of the arrays of nanosheet stacks 104. For example, FIG. 2 illustrates the MDI 130 separating two of the arrays of nanosheet stacks 104 stacked vertically.

The ILD 138 is formed on top of the STI regions 116, the source/drain regions 120, and the inner spacers 122. The ILD 138 may be formed according to known techniques.

The inner spacers 122, the gate spacers 126, the BDI 128, the MDI 130, and the ILD 138 are composed of any suitable interlayer dielectric material (though not necessarily the same material), such as, for example, oxides such as silicon oxide (SiOₓ), nitrides such as silicon nitride (SiₓN_{y}), and/or low-κ materials such as SiCOH or SiBCN. In another embodiment, they are composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, they are self-planarizing material such as a spin-on glass (SOG) or a spin-on low-k dielectric material such as SiLK™. As noted above, the inner spacers 122, the gate spacers 126, and the ILD 138 may be composed of any of the above materials but all are not necessarily the same material(s).

The structure 100 further includes dummy gates 132 and a hard mask 134.

As illustrated, the dummy gates 132 are formed on top of the silicon channels 124 and the sacrificial gates 108 in between gate spacers 126. The dummy gates 132 may be formed of a sacrificial material such as polysilicon. The dummy gates 132 are formed according to known techniques.

The hard mask 134 is deposited and subsequently patterned to expose certain portions of the structure 100 according to known techniques. The hard mask 134 can be an organic planarization layer (OPL) or a layer of material that is capable of being planarized or etched by known techniques. In an embodiment, for example, the hard mask 134 can be an amorphous carbon layer able to withstand subsequent processing temperatures. The hard mask 134 can preferably have a thickness sufficient to cover existing structures. After depositing the hard mask 134, an etching technique (e.g., dry etching) is applied to pattern or recess the hard mask 134 according to known techniques. The hard mask 134 is patterned consistent with a size and a location of subsequently formed upper source/drain regions 144. For example, after patterning the mask 134, portions of the dummy gates 132 are exposed (not shown). Specific to the embodiments disclosed herein, the hard mask 134 is patterned selective to the dummy gates 132 and the gate spacers 126.

Although only a limited number of components, devices, or structures are shown and described, embodiments of the present invention shall not be limited by any quantity otherwise illustrated or discussed herein.

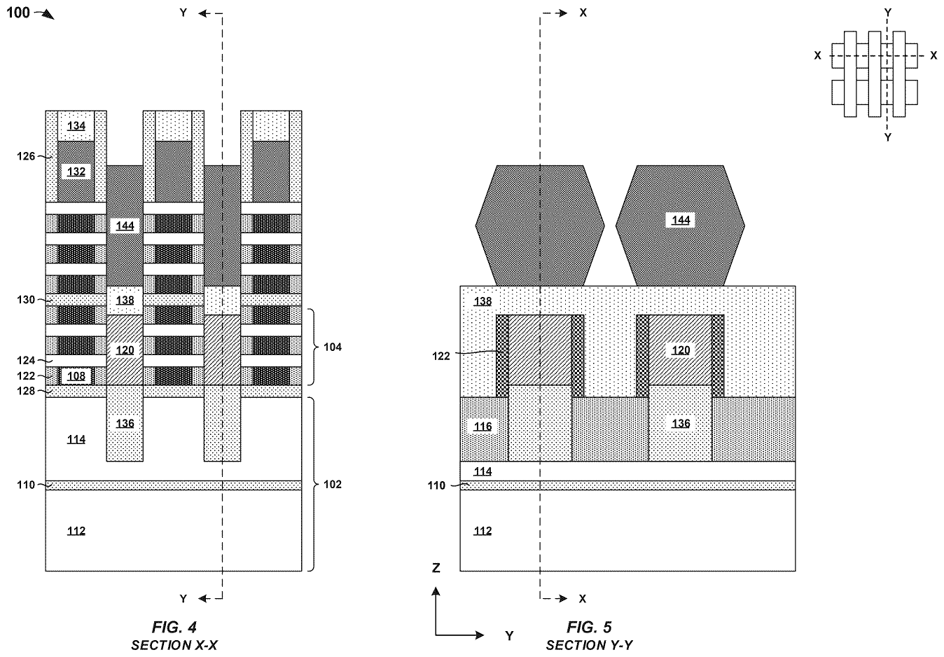

Referring now to FIG. 4 and FIG. 5, a structure 100 is shown during an intermediate step of a method of fabricating a semiconductor structure, according to an embodiment of the invention. FIG. 4 depicts a cross-sectional view of the structure 100 shown in FIG. 5 taken along line XX and FIG. 5 depicts a cross-sectional view of the structure 100 shown in FIG. 4 taken along line YY.

As illustrated, the structure 100 further includes upper source/drain regions 144. The upper source/drain regions 144 may be formed on top of the ILD 138 between adjacent nanosheet stacks 104. Specifically, the upper source/drain regions 144 are disposed between adjacent nanosheet stacks 104 in direct contact with exposed ends of the silicon channels 124. The upper source/drain regions 144 may be epitaxially grown from the exposed ends of the silicon channels 124 according to known techniques. The upper source/drain regions 144 may be formed of a same or similar material as to that described with respect to the source/drain regions 120.

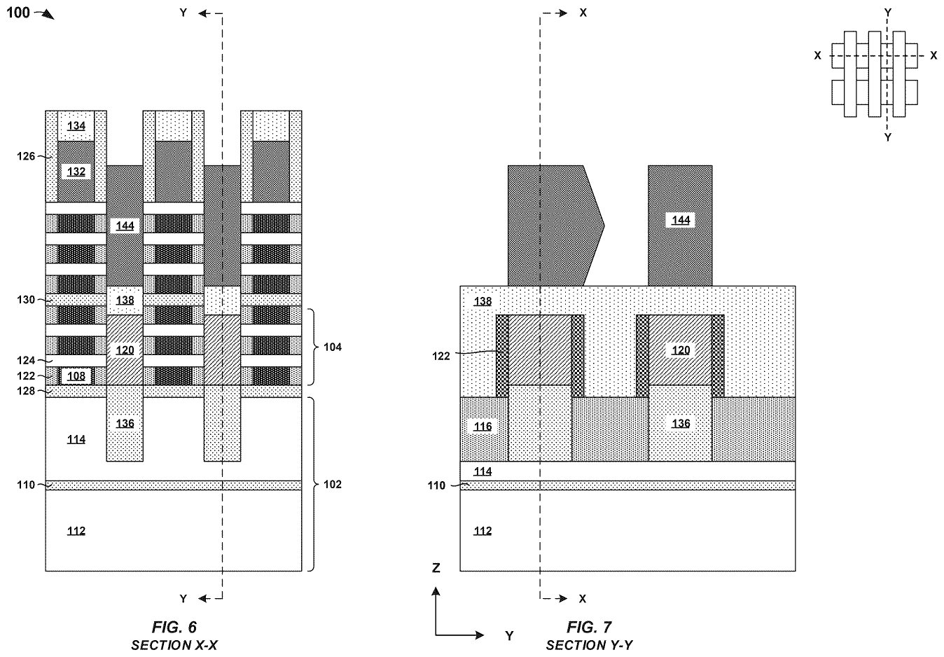

Referring now to FIG. 6 and FIG. 7, the structure 100 is shown during an intermediate step of a method of fabricating a semiconductor structure, according to an embodiment of the invention. FIG. 6 depicts a cross-sectional view of the structure 100 shown in FIG. 7 taken along line XX and FIG. 7 depicts a cross-sectional view of the structure 100 shown in FIG. 6 taken along line YY.

As illustrated by FIG. 7, the upper source/drain regions 144 are cut to remove at least a portion thereof. As illustrated, the upper source/drain regions 144 on the left of FIG. 7 are cut to remove a portion on the left side while the upper source/drain regions 144 on the right of FIG. 7 are cut to remove a portion on both the left and right side. The upper source/drain regions 144 may be patterned and etched according to known techniques. As used herein, a cut may also be referred to as a “trench.”

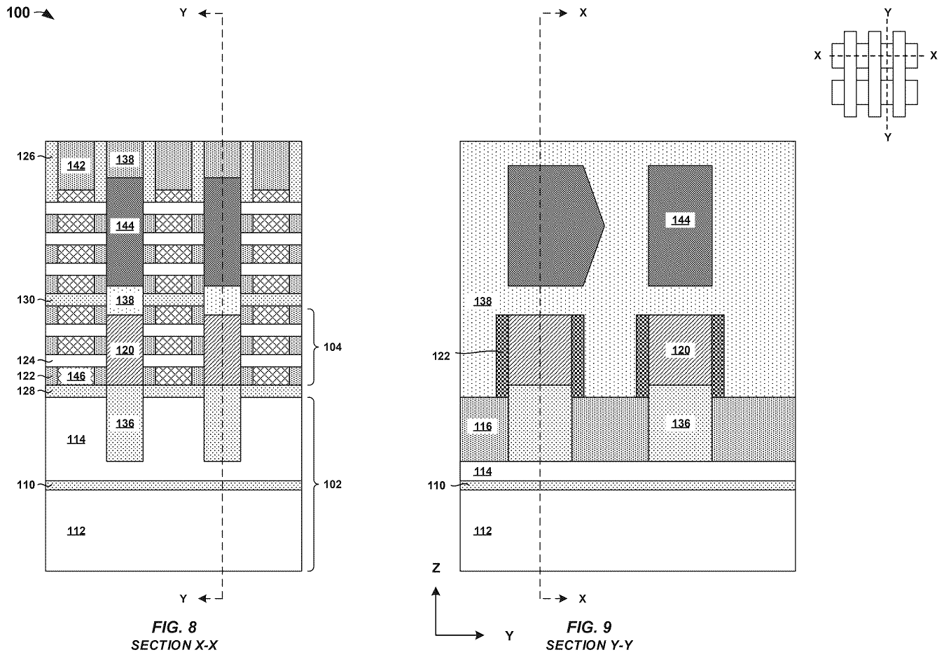

Referring now to FIG. 8 and FIG. 9, the structure 100 is shown during an intermediate step of a method of fabricating a semiconductor structure, according to an embodiment of the invention. FIG. 8 depicts a cross-sectional view of the structure 100 shown in FIG. 9 taken along line XX and FIG. 9 depicts a cross-sectional view of the structure 100 shown in FIG. 8 taken along line YY.

As illustrated, ILD is conformally formed on and around the upper source/drain regions 144, increasing a thickness of the ILD 138.

Further, following removal of the dummy gates 132, the hard mask 134, and sacrificial gates 108, one or more gates 146 are formed in at least a portion of the recess left by the sacrificial gates 108 and the dummy gate 132. The gates 146 may be comprised of a conductive material and formed using known techniques.

Next, a self-aligned contact (SAC) cap 142 is formed on top of the gates 146 in between the gate spacers 126. In embodiments, the SAC cap 142 provides a protective dielectric layer over the gates 146. The SAC cap 142 may be formed with an interlayer dielectric material, for example those used for the inner spacers 122, the gate spacers 126, the BDI 128, MDI 130, and the ILD 138.

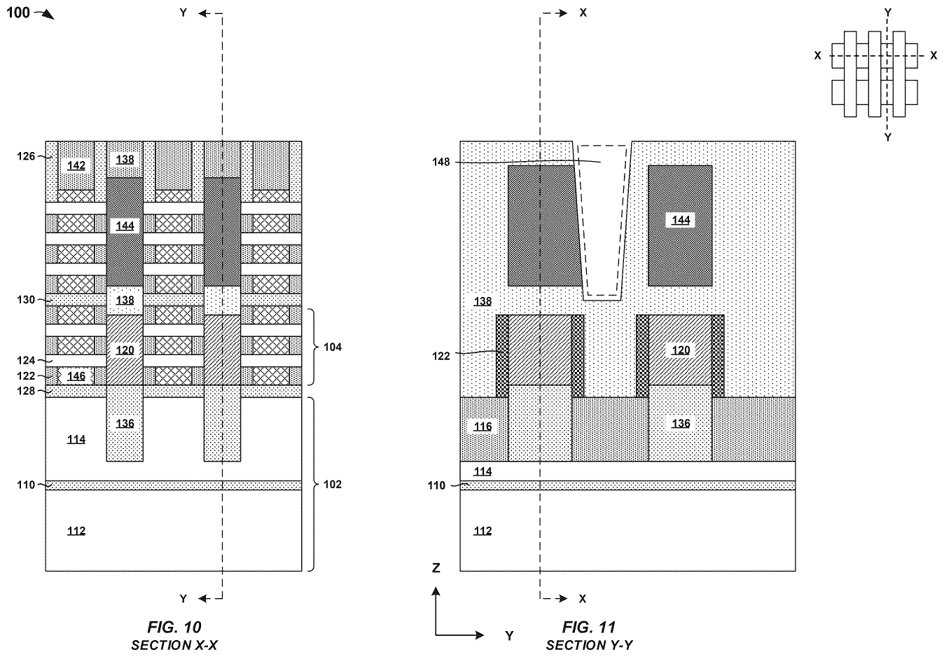

Referring now to FIG. 10 and FIG. 11, the structure 100 is shown during an intermediate step of a method of fabricating a semiconductor structure, according to an embodiment of the invention. FIG. 10 depicts a cross-sectional view of the structure 100 shown in FIG. 11 taken along line XX and FIG. 11 depicts a cross-sectional view of the structure 100 shown in FIG. 10 taken along line YY.

As illustrated by FIG. 11, a cut 148 is made into the ILD 138 between the upper source/drain regions 144. The cut 148 extends at least partially into at least one of the upper source/drain regions 144. With reference to FIG. 11, the cut 148 is made to extend into a right portion of the left upper source/drain regions 144. As further illustrated, the cut 148 extends to a depth beyond the upper source/drain regions 144 without reaching a depth of the source/drain regions 120 and inner spacers 122. The cut 148 may be made using known techniques.

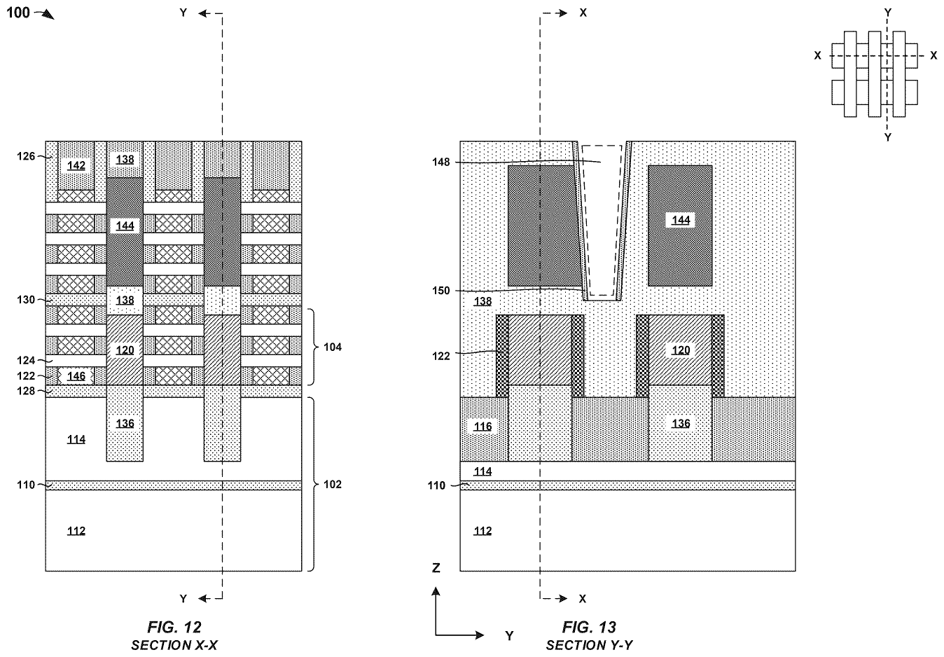

Referring now to FIG. 12 and FIG. 13, the structure 100 is shown during an intermediate step of a method of fabricating a semiconductor structure, according to an embodiment of the invention. FIG. 12 depicts a cross-sectional view of the structure 100 shown in FIG. 13 taken along line XX and FIG. 13 depicts a cross-sectional view of the structure 100 shown in FIG. 12 taken along line YY.

FIG. 12 and FIG. 13 illustrate the structure 100 following a sacrificial spacer formation.

As illustrated, a sacrificial spacer 150 is formed conformally along the inner surface of the cut 148 and, in this embodiment, forms a three-dimensional conical shape having an open top and bottom. The sacrificial spacer 150 leaves a recess within the centroid of the cut 148 with an open bottom that exposes the ILD 138.

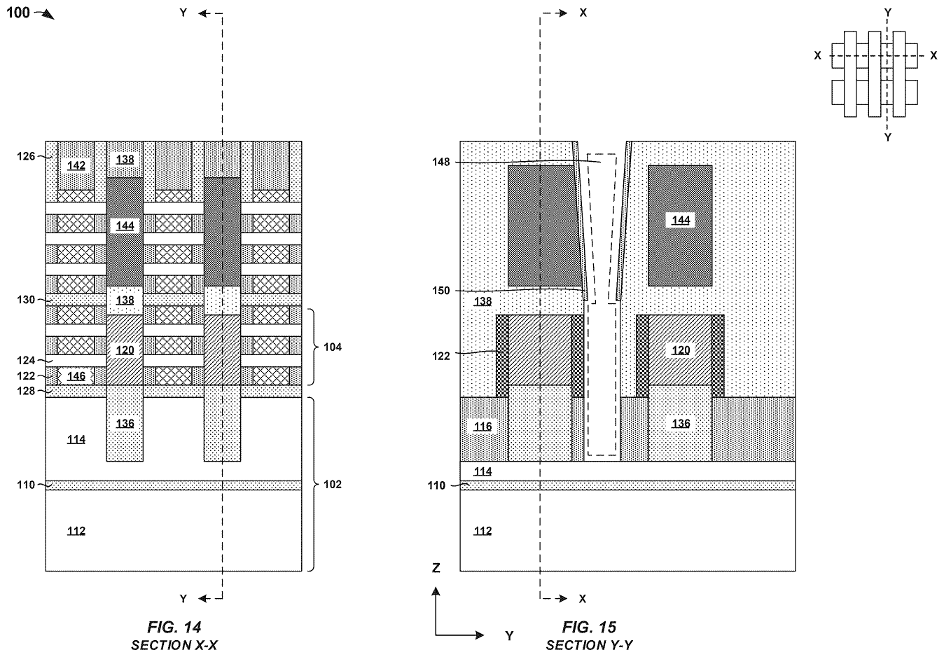

Referring now to FIG. 14 and FIG. 15, the structure 100 is shown during an intermediate step of a method of fabricating a semiconductor structure, according to an embodiment of the invention. FIG. 14 depicts a cross-sectional view of the structure 100 shown in FIG. 15 taken along line XX and FIG. 15 depicts a cross-sectional view of the structure 100 shown in FIG. 14 taken along line YY.

As illustrated, the cut 148 is extended through the ILD 138 down to and exposing the top semiconductor layer 114. In embodiments, the cut 148 may be made by reactive ion etching (RIE). As further illustrated, the cut 148 additionally exposes a side surface of one of the inner spacers 122 as well as side surfaces of the STI regions 116.

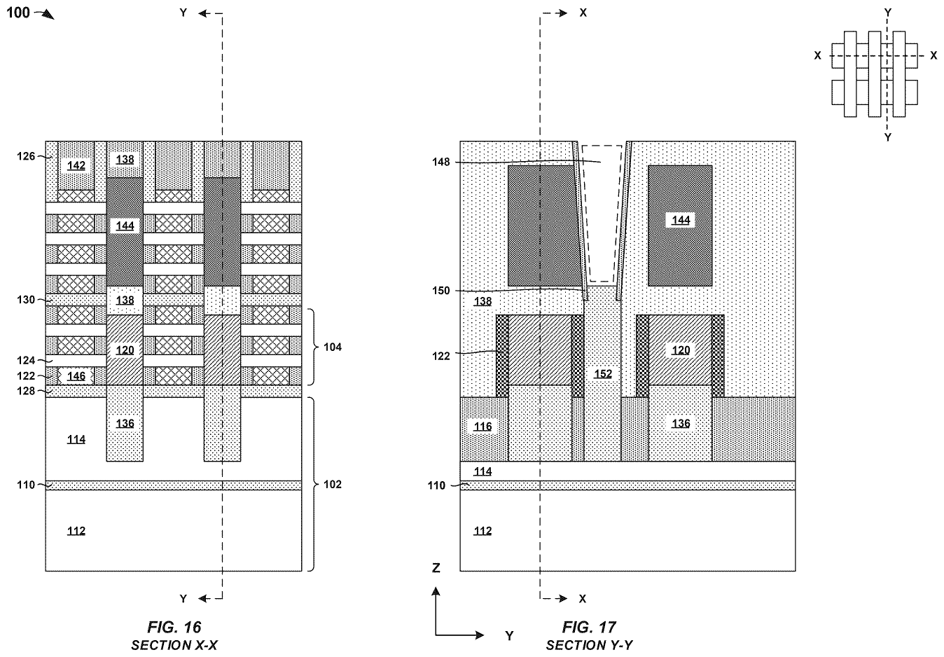

Referring now to FIG. 16 and FIG. 17, the structure 100 is shown during an intermediate step of a method of fabricating a semiconductor structure, according to an embodiment of the invention. FIG. 16 depicts a cross-sectional view of the structure 100 shown in FIG. 17 taken along line XX and FIG. 17 depicts a cross-sectional view of the structure 100 shown in FIG. 16 taken along line YY.

As illustrated, a sacrificial placeholder 152 is formed within a bottom portion of the cut 148. The sacrificial placeholder 152 extends between the top semiconductor layer 114 and the upper source/drain regions 144. As illustrated, the sacrificial placeholder 152 may extend into the sacrificial spacer 150.

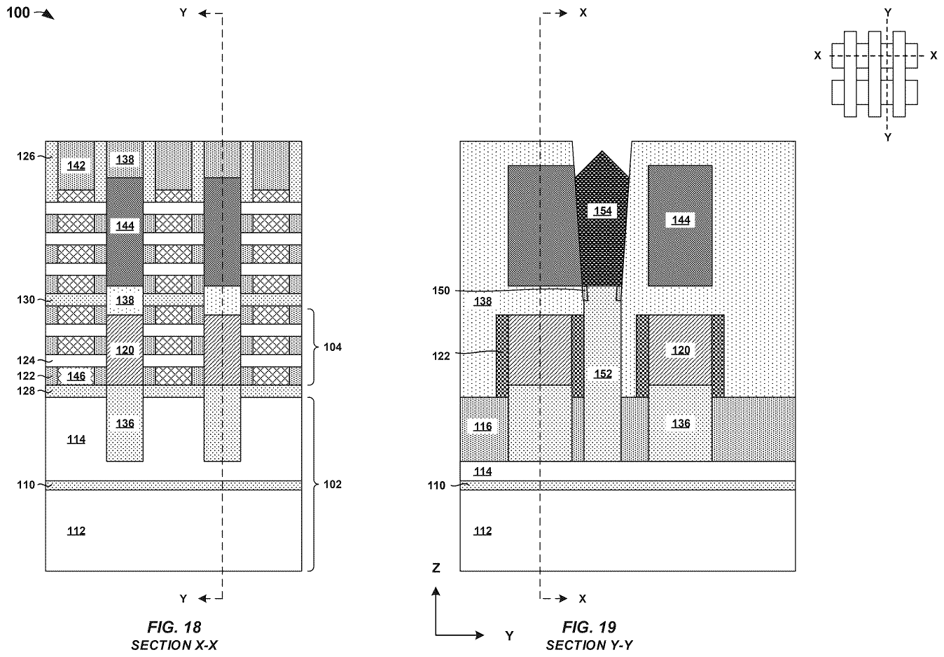

Referring now to FIG. 18 and FIG. 19, the structure 100 is shown during an intermediate step of a method of fabricating a semiconductor structure, according to an embodiment of the invention. FIG. 18 depicts a cross-sectional view of the structure 100 shown in FIG. 19 taken along line XX and FIG. 19 depicts a cross-sectional view of the structure 100 shown in FIG. 18 taken along line YY.

As illustrated, the sacrificial spacer 150 is at least partially removed, leaving segments within an upper portion of the sacrificial placeholder 152. The sacrificial spacer 150 may be removed using known techniques.

Next, an upper source/drain contact 154 is formed within the cut 148. As illustrated, the upper source/drain contact 154 makes contact with a top surface of the sacrificial placeholder 152 and at least one of the upper source/drain regions 144. As further illustrated, an upper portion of the upper source/drain contact 154 has the epitaxial extension above an upper surface of the upper source/drain regions 144 without reaching a top surface of the ILD 138.

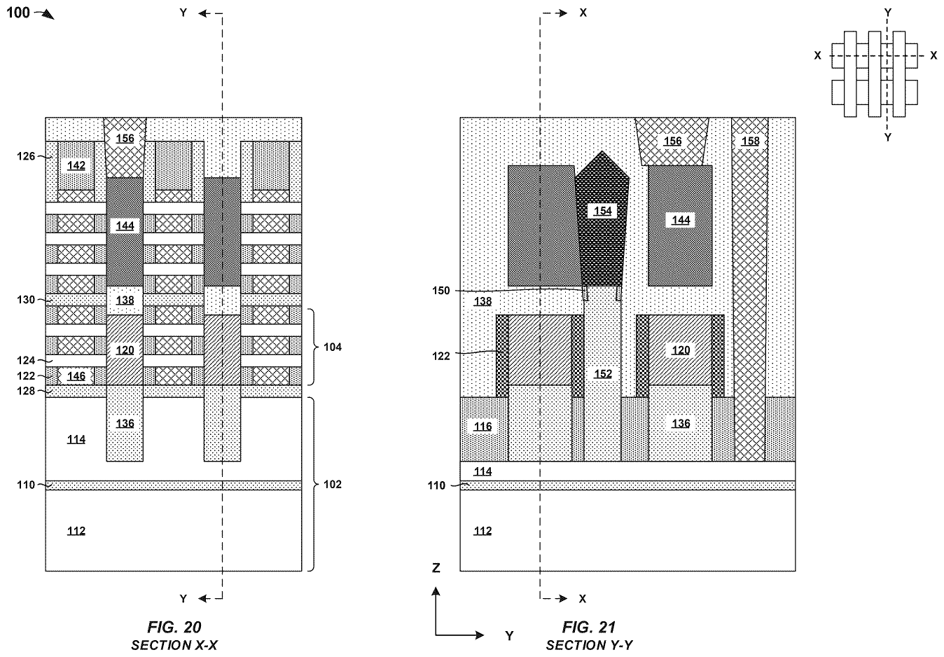

Referring now to FIG. 20 and FIG. 21, the structure 100 is shown during an intermediate step of a method of fabricating a semiconductor structure, according to an embodiment of the invention. FIG. 20 depicts a cross-sectional view of the structure 100 shown in FIG. 21 taken along line XX and FIG. 21 depicts a cross-sectional view of the structure 100 shown in FIG. 20 taken along line YY.

As illustrated, additional ILD is conformally formed on top of the contact 154, the gate spacers 126, the SAC cap 142, and the ILD 138, resulting in the ILD 138 extending up to the middle-of-line 106.

Next, the ILD 138 is patterned, cut, and filled to form a top contact 156 and a top contact 158. As illustrated, the top contact 156 is formed on top of and making contact with at least one of the upper source/drain regions 144 between adjacent gate spacers 126. As further illustrated, a top contact 158 is formed through the ILD 138 and at least partially into the STI regions 116.

FIG. 20 and FIG. 21 illustrate a key benefit of the claimed invention in that the top contact 158 (RV) is moved to a side of the stacked FET, reducing congestion and increasing T2T distance. This solves the major issue of device contact to epitaxy growth shorting, resulting in superior device performance. Further, the interlayer dielectric formation ensures confinement of the epitaxy and no tip-to-tip shorting.

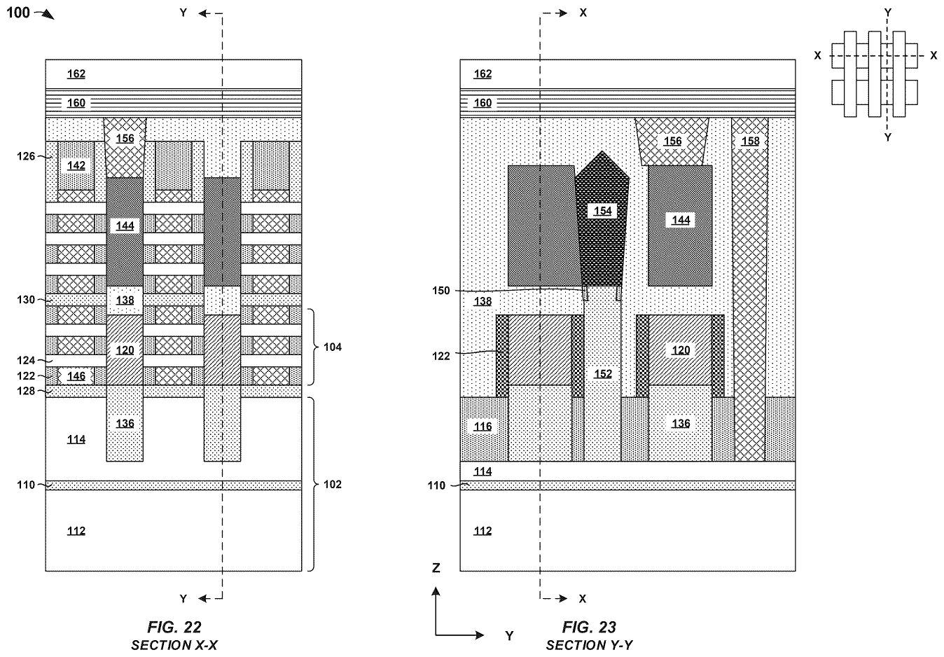

Referring now to FIG. 22 and FIG. 23, the structure 100 is shown during an intermediate step of a method of fabricating a semiconductor structure, according to an embodiment of the invention. FIG. 22 depicts a cross-sectional view of the structure 100 shown in FIG. 23 taken along line XX and FIG. 23 depicts a cross-sectional view of the structure 100 shown in FIG. 22 taken along line YY.

As illustrated, a back-end-of-line (BEOL) 160 is conformally formed on top of the ILD 138, the contact 156, and the top contact 158. The BEOL 160 provides signal powering and routing functionalities to the transistors through, for example, the one or more frontside S/D contacts and/or contacts to the gates of the transistors. The BEOL 160 may include vias and metal lines which may be generally referred to as BEOL interconnects. The vias and the metal lines are formed according to known techniques.

A carrier wafer 162 is secured to a top of the structure 100 according to an embodiment of the invention. The carrier wafer 162 is attached, or removably secured, to the BEOL 160. In general, and not depicted, the carrier wafer 162 may be thicker than the other layers. Temporarily bonding the structure 100 to a thicker carrier provides improved handling and additional support for backside processing of thin wafers. In embodiment, the carrier wafer 162 is bonded onto the BEOL 160 such that the semiconductor structure 100 may be flipped up-side-down for further processing from the backside. After backside processing described below, the structure 100 may be de-bonded, or removed, from the carrier wafer 162 according to known techniques.

Hereinafter, the description will be provided with the understanding that the processing is performed from the backside of the structure, although for the ease of illustration, figures and/or drawings of the semiconductor structure will still be provided in an upside-up fashion or orientation. That is, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

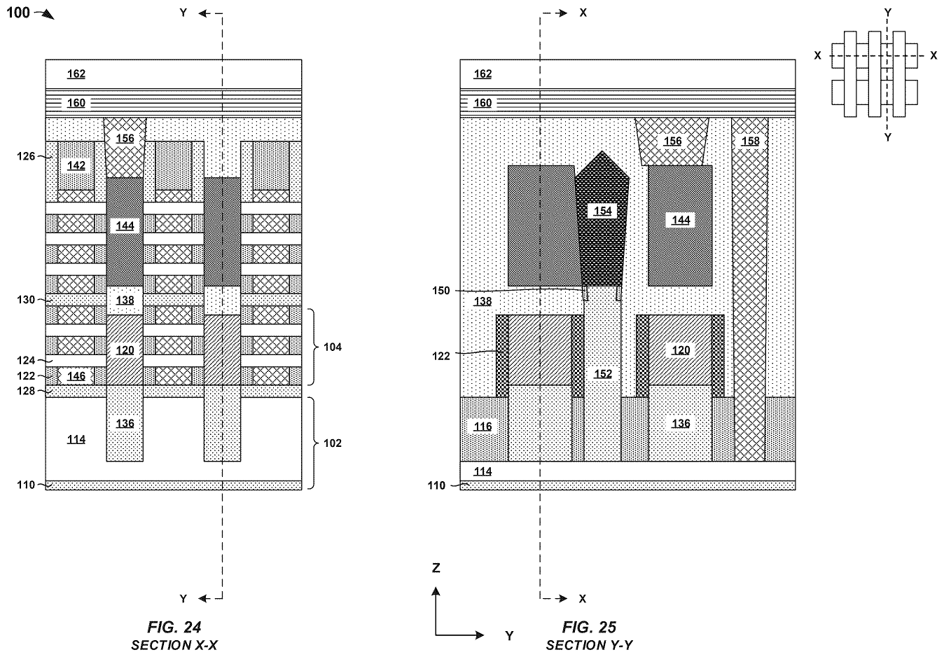

Referring now to FIG. 24 and FIG. 25, the structure 100 is shown during an intermediate step of a method of fabricating a semiconductor structure, according to an embodiment of the invention. FIG. 24 depicts a cross-sectional view of the structure 100 shown in FIG. 25 taken along line XX and FIG. 25 depicts a cross-sectional view of the structure 100 shown in FIG. 24 taken along line YY.

As illustrated, the base substrate 112 is removed from the structure 100, exposing the etch stop layer. The base substrate 112 may be removed according to known techniques.

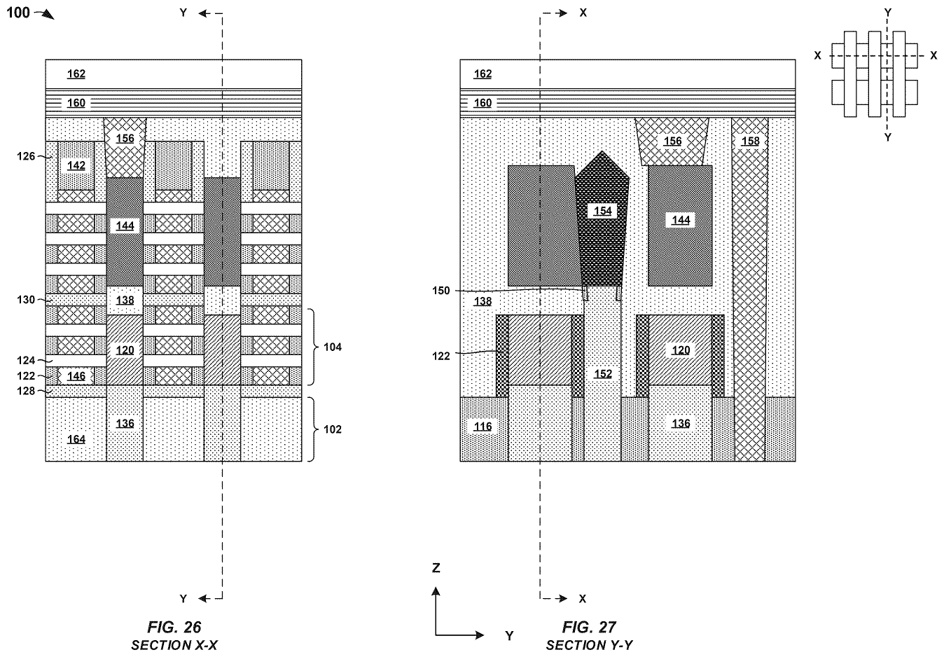

Referring now to FIG. 26 and FIG. 27, the structure 100 is shown during an intermediate step of a method of fabricating a semiconductor structure, according to an embodiment of the invention. FIG. 26 depicts a cross-sectional view of the structure 100 shown in FIG. 27 taken along line XX and FIG. 27 depicts a cross-sectional view of the structure 100 shown in FIG. 26 taken along line YY.

First, the etch stop layer 110 is removed according to known techniques. Then, the top semiconductor layer 114 is removed up to the BDI 128.

Next, a backside interlayer dielectric (BILD) 164 is deposited conformally on the BDI 128. As illustrated, the BILD 164 is formed at least up to a height of the placeholders 136 and STI regions 116. CMP may then be used to planarize the surface.

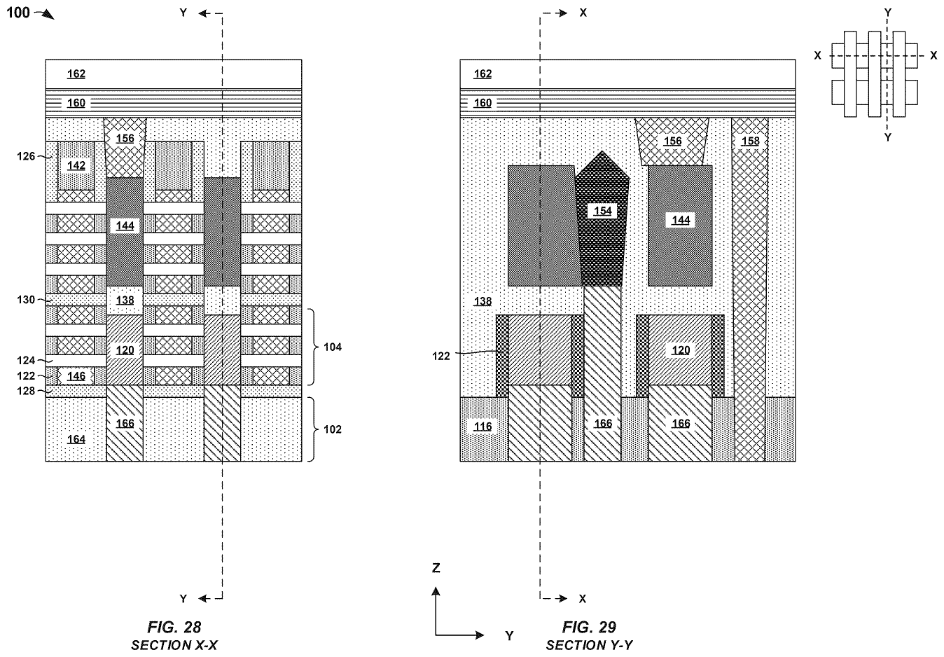

Referring now to FIG. 28 and FIG. 29, the structure 100 is shown during an intermediate step of a method of fabricating a semiconductor structure, according to an embodiment of the invention. FIG. 26 depicts a cross-sectional view of the structure 100 shown in FIG. 27 taken along line XX and FIG. 27 depicts a cross-sectional view of the structure 100 shown in FIG. 26 taken along line YY.

As illustrated, the placeholders 136 and sacrificial spacer 150 are removed to form backside contacts (BSCA) 166. The placeholders 136 and the sacrificial spacer 150 may be removed according to known techniques. Then, as illustrated, the BSCA 166 are formed in contact with the source/drain regions 120 with known conductive materials using known techniques.

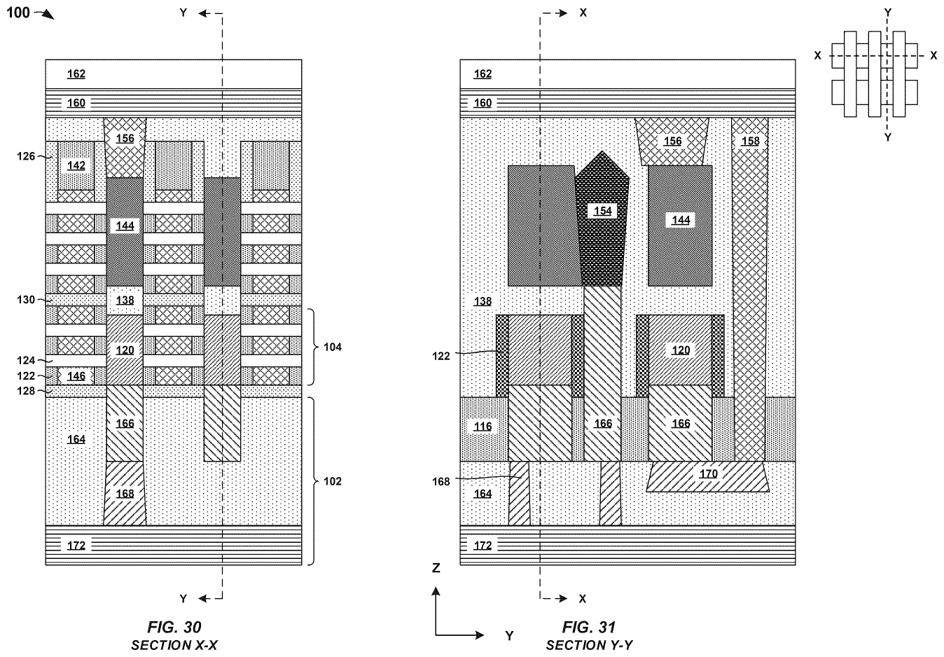

Referring now to FIG. 30 and FIG. 31, the semiconductor structure 100 is shown during an intermediate step of a method of fabricating a semiconductor structure, according to an embodiment of the invention. FIG. 30 depicts a cross-sectional view of the structure 100 shown in FIG. 31 taken along line XX and FIG. 31 depicts a cross-sectional view of the structure 100 shown in FIG. 30 taken along line YY.

As illustrated, ILD is deposited conformally on the BILD 164 before being patterned and cut to form backside vias 168 and a backside source/drain contact 170. The ILD deposition, patterning, cutting, and filling may be performed according to known techniques.

Lastly, backside interconnects 172 is deposited conformally on the BILD 164, the backside vias 168, and the backside source/drain contact 170. The backside interconnects 172 may include CVD or PVD grown metal interconnects.

With continued reference to FIG. 30 and FIG. 31, and according to an embodiment, the structure 100 includes a top transistor stacked on a bottom transistor, wherein top nanosheet stacks of the top transistor are vertically aligned to bottom nanosheet stacks of the bottom transistor, and wherein a top source/drain region of the top transistor is connected to backside interconnects by an extension region, a backside contact, and a backside via.

With continued reference to FIG. 30 and FIG. 31, and according to an embodiment, a bottom source/drain region of the bottom transistor is confined by spacers.

With continued reference to FIG. 30 and FIG. 31, and according to an embodiment, the backside contact is isolated from the bottom source/drain region by the spacers.

With continued reference to FIG. 30 and FIG. 31, and according to an embodiment, the backside contact is isolated from a backside contact of the bottom transistor by a shallow trench isolation (STI) region.

With continued reference to FIG. 30 and FIG. 31, and according to an embodiment, the extension region has different top surface than the top source/drain region.

With continued reference to FIG. 30 and FIG. 31, and according to an embodiment, the extension region has a different bottom surface than the top source/drain region.

With continued reference to FIG. 30 and FIG. 31, and according to an embodiment, the extension region is connected to the top source/drain region through sidewall surfaces.

With continued reference to FIG. 30 and FIG. 31, and according to an embodiment, the extension region is isolated from a second top source/drain region by an interlayer dielectric (ILD).

With continued reference to FIG. 30 and FIG. 31, and according to an embodiment, the structure further comprises a top contact connecting a back end of line (BEOL) to a backside source/drain contact, and wherein the backside source/drain contact connects to a backside contact of the bottom transistor.

With continued reference to FIG. 30 and FIG. 31, and according to an embodiment, the backside contact connects to a second bottom source/drain region of the bottom transistor.

With continued reference to FIG. 30 and FIG. 31, and according to an embodiment, the backside contact is isolated from the second bottom source/drain contact by a shallow trench isolation (STI) region.

With continued reference to FIG. 30 and FIG. 31, and according to an embodiment, the top contact is isolated from a second top source/drain region by an interlayer dielectric (ILD).

With continued reference to FIG. 30 and FIG. 31, and according to an embodiment, a second top contact connects the BEOL with the second top source/drain region.

With continued reference to FIG. 30 and FIG. 31, and according to an embodiment, the bottom source/drain region is connected to the backside interconnects by a second backside contact and a second backside via.

With continued reference to FIG. 30 and FIG. 31, and according to an embodiment, the top source/drain region and the bottom source/drain region are connected to the BEOL.

With continued reference to FIG. 30 and FIG. 31, and according to an embodiment, the second top source/drain region and the second bottom source/drain region are connected to the backside interconnects.

With continued reference to FIG. 30 and FIG. 31, and according to an embodiment, the structure includes a top transistor stacked on a bottom transistor, wherein a top source/drain region of the top transistor is connected to backside interconnects by an extension region and backside contact.

With continued reference to FIG. 30 and FIG. 31, and according to an embodiment, the extension region is formed on a sidewall of the top source/drain region.

With continued reference to FIG. 30 and FIG. 31, and according to an embodiment, the backside contact is isolated from a bottom source/drain region of the bottom transistor by sidewalls.

With continued reference to FIG. 30 and FIG. 31, and according to an embodiment, a method includes forming a bottom layer device source/drain region with spacer confinement and forming a top layer device source/drain region without spacer confinement. The method further includes forming a backside contact trench for the top layer device source/drain region through a sidewall surface of the top layer device source/drain region and forming a backside contact placeholder for the top layer device source/drain region. In addition, the method includes forming a trench epi to connect the top layer device source/drain region to the backside contact placeholder and flipping a wafer on which the top layer device and the bottom layer device are formed. Lastly, the method includes removing the backside contact placeholder and forming a backside contact.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A structure comprising:
a top transistor stacked on a bottom transistor, wherein top nanosheet stacks of the top transistor are vertically aligned to bottom nanosheet stacks of the bottom transistor, and wherein a top source/drain region of the top transistor is connected to backside interconnects by an extension region, a backside contact, and a backside via.

2. The structure of claim 1, wherein a bottom source/drain region of the bottom transistor is confined by spacers.

3. The structure of claim 2, wherein the backside contact is isolated from the bottom source/drain region by the spacers.

4. The structure of claim 1, wherein the backside contact is isolated from a backside contact of the bottom transistor by a shallow trench isolation (STI) region.

5. The structure of claim 1, wherein the extension region has different top surface than the top source/drain region.

6. The structure of claim 1, wherein the extension region has a different bottom surface than the top source/drain region.

7. The structure of claim 1, wherein the extension region is connected to the top source/drain region through sidewall surfaces.

8. The structure of claim 1, wherein the extension region is isolated from a second top source/drain region by an interlayer dielectric (ILD).

9. The structure of claim 1, further comprising:
a top contact connecting a back end of line (BEOL) to a backside source/drain contact, and wherein the backside source/drain contact connects to a backside contact of the bottom transistor.

10. The structure of claim 9, wherein the backside contact connects to a second bottom source/drain region of the bottom transistor.

11. The structure of claim 10, wherein the backside contact is isolated from the second bottom source/drain contact by a shallow trench isolation (STI) region.

12. The structure of claim 10, wherein the top contact is isolated from a second top source/drain region by an interlayer dielectric (ILD).

13. The structure of claim 12, wherein a second top contact connects the BEOL with the second top source/drain region.

14. The structure of claim 2, wherein the bottom source/drain region is connected to the backside interconnects by a second backside contact and a second backside via.

15. The structure of claim 10, wherein the top source/drain region and the bottom source/drain region are connected to the BEOL.

16. The structure of claim 12, wherein the second top source/drain region and the second bottom source/drain region are connected to the backside interconnects.

17. A structure comprising:
a top transistor stacked on a bottom transistor, wherein a top source/drain region of the top transistor is connected to backside interconnects by an extension region and backside contact.

18. The structure of claim 17, wherein the extension region is formed on a sidewall of the top source/drain region.

19. The structure of claim 17, wherein the backside contact is isolated from a bottom source/drain region of the bottom transistor by sidewalls.

20. A method comprising:
forming a bottom layer device source/drain region with spacer confinement;
forming a top layer device source/drain region without spacer confinement;
forming a backside contact trench for the top layer device source/drain region through a sidewall surface of the top layer device source/drain region;
forming a backside contact placeholder for the top layer device source/drain region;
forming a trench epi to connect the top layer device source/drain region to the backside contact placeholder;
flipping a wafer on which the top layer device and the bottom layer device are formed;
removing the backside contact placeholder; and
forming a backside contact.
